(19) United States
(12) Patent Application Publication
(10) Pub. No.: US 2024/0282605 A1
(43) Pub. Date: Aug. 22, 2024

(54) LOUVER DESIGN FOR ELIMINATING LINE OF SIGHT

(71) Applicant: Applied Materials, Inc., Santa Clara, CA (US)

(72) Inventors: Rupankar CHOUDHURY, Bangalore (IN); Sanjay G. KAMATH, Fremont, CA (US); Sridhar BACHU, Bangalore (IN)

(73) Assignee: Applied Materials, Inc., Santa Clara, CA (US)

(21) Appl. No.: 18/172,149

(22) Filed: Feb. 21, 2023

(51) Int. Cl. H01L 21/67; F24F 13/14; F24F 13/32; H01L 21/673

(52) U.S. Cl. CPC H01L 21/6719; F24F 13/1413; F24F 13/1486; F24F 13/32; H01L 21/67383; H01L 21/67393

(57) ABSTRACT

An apparatus and system for minimizing particle return to the processing area of a processing chamber are disclosed herein. In one example, a particle shield for a semiconductor vacuum processing chamber includes an annular ring, a plurality of rib supports, and a plurality of louver fins. The annular ring has top surface, a bottom surface, and a plurality of cutaways. The top surface has an upper outer portion and a lower inner portion. The plurality of rib supports are disposed on and supported by the lower inner portion. The plurality of louver fins have a truncated conical shape, a bottom surface of the louver fins supported in a recess formed in a top surface of the rib supports. Each of the plurality of louver fins are disposed between adjacent concentric louver fins that have an outer diameter greater than an inner diameter of the outwardly adjacent louver fin.

### BACKGROUND

### Field

Embodiments of the present disclosure generally relate to a semiconductor process chamber. More specifically, embodiments of the disclosure relate to a semiconductor process chamber having a particle shield.

### Description of the Related Art

In semiconductor manufacturing, integrated circuits (IC) are formed on semiconductor substrates through various manufacturing steps, including etching, deposition, ion implantation, and annealing. These processes may inadvertently create and deposit undesired particles on surfaces within the processing chamber. These particles may break from the surface and move about the chamber causing process deposition contamination of the semiconductor substrate. Rotating equipment coupled to the processing chamber may draw loose particle towards the equipment and cast the particle towards the processing area. Thus, there is a need for minimizing particle return to the processing area of the chamber for improved semiconductor manufacturing.

### SUMMARY

An apparatus and system for minimizing particle return to the processing area of a semiconductor processing chamber are disclosed herein. In one example, a particle shield for a semiconductor vacuum processing chamber includes an annular ring, a plurality of rib supports, and a plurality of louver fins. The annular ring has top surface, a bottom surface, and a plurality of cutaways. The top surface has an upper outer portion and a lower inner portion. The plurality of rib supports are disposed on and supported by the lower inner portion. The plurality of louver fins have a truncated conical shape, a bottom surface of the louver fins supported in a recess formed in a top surface of the rib supports. Each of the plurality of louver fins are disposed between adjacent concentric louver fins that have an outer diameter greater than an inner diameter of the outwardly adjacent louver fin.

In another example, a system particle shield for a semiconductor vacuum processing chamber includes a chamber, a substrate support pedestal, a vacuum pump, a valve, a louver particle shield with an annular ring, a plurality of rib supports, and a plurality of louver fins. The chamber comprises one or more sidewalls, a bottom wall, and a lid enclosing a chamber interior volume. The substrate support pedestal is disposed within the chamber volume. The vacuum pump is coupled to the chamber and is in fluid communication with the chamber interior volume. The valve is positioned between the chamber and the vacuum pump and is configured to isolate the vacuum pump from the chamber interior volume. The louver particle shield is positioned between the vacuum pump and the chamber. The annular ring of the louver particle shield has a top surface and a bottom surface, and a plurality of cutaways. The top surface of the annular ring has an upper outer portion and a lower inner portion. The plurality of rib supports of the louver particle shield are disposed on and are supported by the lower inner portion of the annular ring. The plurality of louver fins of louver particle shield has a truncated conical shape and a bottom surface of the louver fins supported in a recess formed in a top surface of the rib supports. Each of the plurality of louver fins are disposed between adjacent concentric louver fins which have an outer diameter greater than an inner diameter of the outwardly adjacent louver fin.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 illustrates a schematic view of a processing chamber according to certain aspects of the present disclosure.

FIG. 2 illustrates an axonometric view of a louver particle shield from FIG. 1, according to certain aspects of the present disclosure.

FIG. 3 illustrates a cross sectional view of the louver particle shield of FIG. 2, according to certain aspects of the present disclosure.

To facilitate understanding, identical reference numerals have been used, where possible, to designate identical elements that are common to the figures. It is contemplated that elements and features of one embodiment may be beneficially incorporated in other embodiments without further recitation.

Many of the details, dimensions, angles, and other features shown in the Figures are merely illustrative of particular implementations. Accordingly, other implementations can have other details, components, dimensions, angles, and features without departing from the spirit or scope of the present disclosure. In addition, further implementations of the disclosure can be practiced without several of the details described below

### DETAILED DESCRIPTION

The present disclosure describes an apparatus and system for minimizing loose particle float within a processing system. It has been found that contamination of particles in a processing chamber may increase the difficulty of achieving a desired deposition on a substrate. Over time, the deposition of particles from various processes on unintended surfaces within the chamber begin to accumulate and flake off causing loose particles within the process volume of the processing chamber. Cleaning processes are utilized to reduce the amount of surface build up; however, between cycles of cleaning, these surface particles may begin to flake. These flaked particles are known to break and fall into the processing volume of the chamber and may land on surfaces designated for processing, such as the substrate, causing imperfections. These undesired particles may also be inadvertently forced to break off from the surfaces as the chamber pressure reducing equipment reduces the pressure in the process volume. Generally, these loose particles flow towards a vacuum pump impeller, strike the impeller, and are chaotically flung within the processing chamber and may land on the substrate—leading to unacceptable defects. To resolve this issue, a louver particle shield is disclosed herein which impedes the trajectory of the particles which contact an impeller and cause the particles to refrain from returning into the processing chamber volume. This advantageously results in more uniform processing of substrates, increased yield, reduced waste, increased efficiency of processing, and lower cost of ownership.

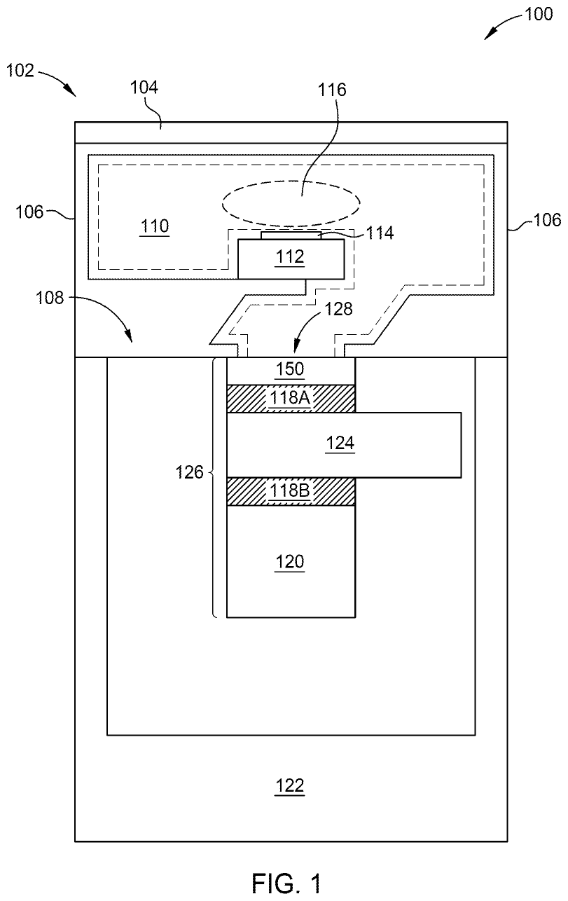

FIG. 1 depicts a schematic view of a processing chamber 100 including a processing chamber body 102 having a substrate support 112 disposed therein for supporting a substrate 114 during processing. The processing chamber 100 may be a vacuum processing chamber, such as an etch reactor processing chamber, an ion implant chamber, a deposition chamber, a plasma treatment chamber, an atomic layer deposition chamber, etc. The processing chamber 100 may be, for example, a processing chamber for carrying out a deposition process, an etching process, an annealing process or a cleaning process, among others on the substrate 114 positioned on the substrate support 112. Representative chambers for carrying out a deposition process include deposition chambers, such as, for example, plasma enhanced chemical vapor deposition (PECVD) chambers, chemical vapor deposition (CVD) chambers, or physical vapor deposition (PVD) chambers. Representative chambers for carrying out an etch process include reactive ion etch chambers, and inductively coupled plasma etch chambers, among others.

In the embodiment of FIG. 1, the processing chamber 100 includes the chamber body 102 having one or more chamber sidewalls 106, a chamber bottom 108, and a chamber lid 104 enclosing a chamber volume 110. The substrate 114 is positioned on the substrate support 112 within the chamber volume 110. In some embodiments, a plasma 116 may be formed within the interior volume 110 of the processing chamber 100 by applying RF power from an RF power source (not shown) to excite processing gases within the interior volume. Plasma formation is ideally controlled for substrate processing; however, there are challenges to a well confined plasma formation that may lead to unintended or residual deposition on a surface other than the targeted surface. For example, residual reactive gases may deposit particles on parts of the chamber body 102, including the chamber lid 104, the one or more chamber sidewalls 106, the chamber bottom 108, and the substrate support 112.

The processing chamber 100 utilizes pressure reducing equipment 126 to reduce the pressure within the interior volume 110 of the chamber body 102 and evacuate processing by-products during processing of the substrate 114. As shown in FIG. 1, the pressure reducing equipment 126 includes a vacuum pump 120 (for example, a turbo pump) coupled to the chamber body 102 in fluid communication with the interior volume 110. The vacuum pump 120 is fluidly coupled to the interior volume 110 of the chamber body 102 and is used to achieve low pressure conditions within the chamber body 102. For example, the vacuum pump 120 may achieve pressure of less than 100 mTorr, such as less than 40 mTorr, or such as less than 20 mTorr while operating at a temperature about 75 degrees Celsius with a rotational speed of up to 24,000 revolutions per min (“RPM”).

The pressure reducing equipment 126 also includes an isolation valve 124 positioned between the chamber body 102 and the vacuum pump 120. The isolation valve 124 may include a gate valve, which can be closed to fluidly separate the interior volume 110 of the chamber body 102 and the vacuum pump 120 for purposes such as, but not limited to, cleaning and maintenance. After a number of designated cycles of processing, a cycle of cleaning is performed. The general sequence to clean a processing chamber 100 is to isolate the vacuum pump 120 from the chamber body 102 using the isolation valve 124 to provide protection against the cleaning agent used for removing deposited particles from interior portions of the chamber body 102 as the vacuum pump impeller may be made of material incompatible with the cleaning agent used to clear the surfaces of the interior volume 110. The isolation valve 124 may be one of various types of typical valves such as, for example, butterfly, ball, v-ball, gate, pendulum, globe, or angle valve suitable to isolate the chamber body 102 from the vacuum pump 120. The isolation valve 124 may be fast acting, having a throttling speed of less than one second, or may be tight shut off to prevent gaseous escape.

Pressure reduction of the interior volume 110 may be a time intensive process that may require up to several hours to achieve ideal low pressure processing conditions. Furthermore, as pressure is reduced within the chamber body 102, a suction effect may be experienced on all surfaces contacting the interior volume. As previously discussed, unwanted particle formation on surfaces within the interior volume 110 may break off and cause defective substrate processing. The suction flow of the pressure reducing equipment 126 floats the particles towards the equipment suction inlet 128.

In some embodiments a pump inlet screen 118 is utilized to prevent large particles from coming in contact with the vacuum pump impellers (not shown) of the vacuum pump 120. The pump screen 118 may be located either upstream or downstream of the isolation valve 124 as shown by pump screen 118A and pump screen 118B in FIG. 1. If located upstream of the isolation valve 124 (e.g., between the chamber body 102 and the isolation valve 124), the screen 118A may be cleaned as it remains exposed to the interior volume 110 of the chamber body 102 when the vacuum pump 120 is isolated from the chamber body 102 during chamber cleaning processes. If located downstream of the isolation valve 124 (e.g., between the isolation valve 124 and the vacuum pump 120), the screen 118B may be protected against, for example, cleaning agents or other processing fluids during chamber cleaning processes by the closed isolation valve 124. The pump screen 118 may include a honeycomb structure designed to capture particles or any broken pieces of substrate larger than 5 millimeters in length to prevent damage to any rotating components of the vacuum pump 120.

In one embodiment, the pressure reducing equipment 126, further includes a louver particle shield 150 disposed between the chamber body 102 and the vacuum pump 120. In the example shown in FIG. 1, the louver particle shield 150 is disposed between the chamber body 102 and the isolation valve 124. The louver particle shield 150 may be used to eliminate or drastically reduce the amount of particle contamination in the chamber body 102. In some embodiments, the louver particle shield 150 may be coupled to the chamber bottom 108. In other embodiments, the louver particle shield 150 may be coupled to the vacuum pump 120 suction side. Optionally, the pump screen 118A may be disposed between the louver particle shield 150 and the vacuum pump 120. In other embodiments, the isolation valve 124 may be disposed below the louver particle shield 150 and the pump screen 118A, e.g., between the screen 118A and the vacuum pump 120.

During substrate processing, in addition to unwanted deposition of particles to the interior of the chamber body 102, unwanted deposition of particles may also take place on the vacuum pump 120 being used to evacuate by-products during deposition processes. In particular, impellers (not shown) of the vacuum pump 120 may be susceptible to unwanted deposition. As the vacuum pump impellers rotate, any loose particles on the surface of the impellers or particles drawn towards the impellers are struck by the impellers causing the particles to bounce off the impellers and towards the direction of the chamber volume 110. The louver particle shield 150 allows loose floating particles to reach the screen 118 or the vacuum pump 120 impellers while simultaneously reducing any particles returning in the chamber by behaving as an obstruction of particle flow.

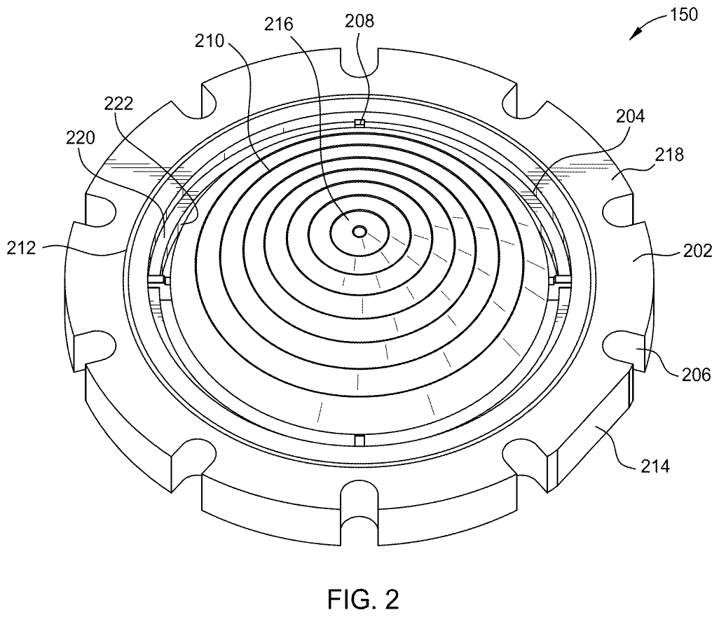

FIG. 2 depicts an exemplary axonometric view of one embodiment of the louver particle shield 150. The louver particle shield 150 includes an annular ring 202, a plurality of rib supports 208, and a plurality of louver fins 210. The annular ring 202 includes two portions, a first portion 218 (also referred as “outer upper portion”) and a second portion 204 (also referred as “inner lower portion”). The first portion 218 of the annular ring 202 includes connection locations 206, a seal recess 212, and optionally an alignment slot 214 for installation. The connection locations 206 may be equally spaced along the circumference of the outer diameter of the annular ring 202. These connection locations 206 may be cutaways as shown in FIG. 2 configured to receive or allow a bolt to pass through for installation in the processing system 100. In another embodiment, the connection locations 206 may be holes drilled through the first portion 218 of the annular ring to align with fastener holes and retain the annular ring 202 in position once installed. In one embodiment, there may be up to twelve connection locations 206. The annular ring 202 may include the circular seal recess 212 to house a gasket about half way between the outer diameter and the inner diameter of the first portion 218 of the annular ring 202. The gasket is used to provide a tight seal against the chamber bottom 108 or portion of equipment that abuts when installed. Typical gaskets used for pressure sealing may include, but not limited to Perfluoroelastomer o-rings, such as FKM or FFKM, capable of handling operating conditions. Optionally the first portion 218 of the annular ring 202 may be keyed to provide desired alignment with adjacent equipment surfaces to prevent misalignment during installation. In one embodiment, the annular ring 202 may be constructed from aluminum. The aluminum may be polished to provide a smooth surface as rough surfaces may encourage particle accumulation.

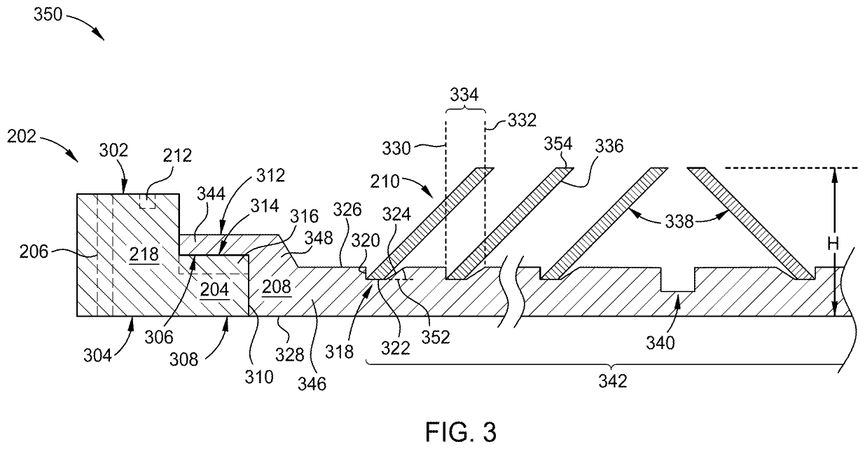

The second portion 204 of the annular ring 202 has a top surface 220, an inner surface 222, and a bottom surface (not shown on FIG. 2) opposite the top surface 306. FIG. 3 depicts these surfaces as the top surface 306, an inner surface 310, and a bottom surface 308. The outer diameter of the second portion 204 of the annular ring 202 may be integral with the inner diameter of the first portion 218 of the annular ring 202. The top surface 306 of the second portion 204 of the annular ring 202 is stepped down between 0.01 to 0.75 inches from a top surface 302 of the first portion 218 of the annular ring 202. In some embodiments, the top surface 306 may include keyed recesses 316 that may be configured to receive rib supports 208. These keyed recesses 316 may be circular, curved, parabolic, squared, or substantially rectangular with curved end. The plurality of keyed recesses 316 may be 0.05 to 0.5 inches deep from the top surface 306 of the second portion 204 of the annular ring 202. The depth of these keyed recesses 316 may be determined by the operating parameters of the vacuum pump 120. For example, a spinning object may induce a similar motion to a static object and thus the depth of the recesses 316 may be determined to counter the rotational force caused by the impeller rotation. In other embodiments, the rib supports 208 may be positioned by pins (not shown) extending out of the top surface 306 (or out of the keyed recess 316) of the second portion of the annular ring 204. In yet another embodiment, the top surface 306 is flat and the rib supports 208 rest on the top surface 306 of the second portion 204 of the annular ring 202. The bottom surface 308 of the second portion 204 of the annular ring 202 may be aligned with the first portion 218 of the annular ring 202 such that the louver particle shield 150 has a substantially flat bottom. The annular ring 202 may be constructed of a single piece of material and formed into the represented shape of FIG. 3.

FIG. 3 depicts an exemplary cross sectional schematic of a rib support 208 coupled to the annular ring 202 and supporting the last couple of rows of louver fins 210. The rib support 208 includes three portions. A first portion 344 of the rib support 208 has two surfaces, an upper surface 312 and a lower surface 314. In some embodiments, when assembled, the lower surface 314 of the first portion 344 of the rib support 208 makes contact with the top surface 306 of the second portion 204 of the annular ring 202. In other embodiments, the lower surface 314 of the first portion 344 of the rib support 208 makes contact with the second portion 204 of the annular ring 202 within the keyed recess 316. An upper profile of the first portion 344 of the rib support 208 may be circular, curved, parabolic, squared, or substantially rectangular with a curved end to match the embodiment of the keyed recesses 316 of the annular ring 202.

A second portion 346 of the rib support 208 has two surfaces, an above surface 326 and a below surface 328. In some embodiments the second portion 346 may be formed from a single piece of material, such as aluminum. The above surface 326 may have a plurality of surface positioning locations 318 utilized to position the louver fins 210. In one embodiment, a rib support 208 may be formed from strategic bending of flat aluminum into the desired shape to rest on the annular ring 202 and support the louver fins 210 at the desired surface positioning locations 318. In the aforementioned embodiment, the below surface 328 would result in a mirrored construction of the above surface 326. In yet another embodiment, the rib support 208 may be constructed from a single piece of material with the surface positioning locations 318 machined into the above surface 326 of the second portion 346 of the rib support 208 with a substantially flat below surface 328 as shown in FIG. 3. In some embodiments the rib support 208 may be cast or forged.

Each rib support 208 has a length less than the outer diameter of the second portion 204 of the annular ring. Each rib support 208 also has a coupling design 340 at half the length. The coupling design 340 of the rib support 208 has a cross over structure to couple with adjacent rib supports. In one embodiment with a two rib support design, one rib support 208 may have an above block cutaway (as shown in FIG. 3) and the other rib support may have a below block cutaway (not shown) so as to provide a perpendicular coupling to provide the necessary support for the louver fins 210. In other embodiments where more than two rib supports cross each other at their center of lengths, the cut outs may be tiered so as the coupled rib supports stack upon each other.

The plurality of surface positioning locations 318 may be directional. Within each half length of the rib supports 208, each of the plurality of the surface positioning locations 318 has three faces: a first face 320, a second face 322, and a third face 324. The first face 320 may be substantially perpendicular to the above surface 326 of the rib support 208. The second face 322 may be substantially parallel to the above surface 326 of the rib support 208. The third face 324 may be of various angles such as, but not limited to, between 45 to 150 degrees from the plane of the second face 322 or 0 to 30 from second face reference line 352. The angle selected may allow for proper alignment of the louver fins 210.

A third portion 348 of the rib support 208 couples the first portion 344 to the second portion 346 in a suitable manner. Suitable coupling of the first and second portion, 344 and 346, respectively, of the rib support 208 may be, but not limited to, a weld or fastener. In some embodiments, the third portion 348 is a transition portion from the first 344 portion of the rib support 208 to the second portion 346 of the rib support 208 having a strategic bend. In some embodiments the length of the third portion 348 allows the below surface 328 to be substantially aligned with a bottom surface 304 of the first portion 218 of the annular ring 202 as depicted in FIG. 3.

Each of the plurality of louver fins 210 include a disk-like structure with a center cut out pressed into a cone shape. This results in a shallow cone structure with a truncated top where the outside angle of the louver fin is about 135 to 170 degrees from horizontal or stated differently, where the inside angle of the louver fin is about 10 to 45 degrees, such as about 10 to 30 degrees, or such as about 15 to 30 degrees from horizontal. While FIG. 3 depicts the cross sectional shape of the louver fins 210 to be substantially flat, other embodiments such as, but not limited to, a curved profile are contemplated. Each of the plurality of louver fins 210 has an inner diameter 332 larger than the outer diameter 330 of the concentric smaller adjacent louver fin 210 thereby having an overlap of coverage 334. A fully assembled louver particle shield 350 includes multiple concentric louver fins 210, each having an overlap of coverage 334 to the respective smaller adjacent louver fin 210. The concentric louver fins have a center piece 216 as illustrated in FIG. 2. The overlap of coverage 334 of the louver fins 210 provides the benefit of having no line of sight between the interior volume 110 of the chamber body 102 and the vacuum pump 120 when looking directly down, or up, on the louver particle shield 150 within the louver fin region 342. The lack of line of sight significantly reduces the likelihood of a particle returning back into the interior volume 110 of the chamber body 102 after being struck by the vacuum pump 120 impeller. The overlap of coverage 334 ensures a particle trajectory is changed within the region of the louver fins 342. As previously mentioned, a particle may be struck by the impeller of the vacuum pump 120 and cast, for example, in an angle normal to the impeller surface. In the embodiment of FIG. 1, the particle would then be cast in an upward direction and impact an inner surface 336 of a louver fin 210 and bounce back down toward the impellers and or bounce about. The particle would cycle through this repetitive process until the particle is broken down and expelled through the vacuum pump 120, captured through a pump screen 118, or attaches to the inner surface 336 of the louver fins 210 when the louver fins have reached end of life.

The center piece 338 of FIG. 3 (or 216 of FIG. 2) of the louver particle shield 350 is circumscribed by larger concentric louver fins as shown in FIGS. 2 and 3. The center piece 338 is mounted, similar to the louver fins 210, to the surface positioning locations 318 of the rib supports 208. Similar to the overlap of coverage 334 present in the louver fin region 342, there is also an overlap of coverage 334 between the center piece 338 and the adjacent larger louver fin 210. The center piece 338 is cone shaped with a center cut out. In some embodiments, the angle of the center piece 338 mirrors the angle of plurality of louver fins 210. The louver particle shield 350 still exhibits no line of sight between the chamber body 102 and the vacuum pump 120 even though the center is cut out. The rib support 208 may provide necessary coverage covering the exposed center cut out. In some embodiments, the center piece 338 is a single formed cone shape without the center cut out. The center piece 338 and the plurality of louver fins may be made from aluminum. In one embodiment, the aluminum is die cast. In another embodiment the aluminum of the plurality of louver fins may be aluminum spun. In yet another one embodiment, optionally combined with other embodiments previously described, the aluminum is polished to minimize particle adhesion.

The louver fins 210 and the center piece 338 may be connected or fastened to the rib supports 208 by any suitable manner. These include, but are not limited to, tack or spot welding, vertical retention pins, fasteners, and the like. In one embodiment, the louver fins, including the center piece, may extend beyond the height of the top surface 302 of the annular ring 202 but do not exceed a profile height, H, of about one inch form the bottom surface 304 of the annular ring 202 to the top end 354 of the plurality of louver fins 210. It has been discovered that one inch height of the louver particle shield 350 provides for a minimal redesign in the processing chamber system 100 component spacing. It has been contemplated that the length of each of the louver fins and center piece may vary so long as the profile height, H, is not exceeded thereby allowing for multiple combinations of angles and lengths to achieve the desired overlaps of louver fins and profile height.

While the foregoing utilizes specific equipment terminology, it is contemplated that other terms may be used to refer to the same, or similar aforementioned equipment. A specific term is not meant to be limiting. For example, a vacuum pump may be referred to as a turbo pump, an evacuation pump, pressure reducing machinery or equipment, and the like.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby.

Certain embodiments and features have been described using a set of numerical minimum values and a set of numerical maximum values. It should be appreciated that ranges including the combination of any two values, e.g., the combination of any minimum value with any maximum value, the combination of any two minimum values, and/or the combination of any two maximum values are contemplated unless otherwise indicated. Certain minimum values, maximum values, and ranges appear in one or more claims below.

What is claimed is:

1. A particle shield for a semiconductor vacuum processing chamber, the particle shield comprising:
an annular ring having a top surface and a bottom surface, the annular ring having a plurality of cutaways, the top surface of the annular ring having an upper outer portion and a lower inner portion;
a plurality of rib supports disposed on and supported by the lower inner portion of the annular ring; and
a plurality of louver fins having a truncated conical shape, a bottom surface of the louver fins supported in a recess formed in a top surface of the rib supports, each of the plurality of louver fins disposed between adjacent concentric louver fins has an outer diameter greater than an inner diameter of the outwardly adjacent louver fin.

2. The particle shield of claim 1, wherein each of the plurality of louver fins is oriented at an angle of 10 to 45 degrees relative to the bottom surface of the annular ring.

3. The particle shield of claim 1, wherein the annular ring comprises a seal recess between the outer and inner diameter of the outer annular ring, the annular ring having a keyed portion for installation alignment.

4. The particle shield of claim 1, wherein each of the plurality of the rib supports have a recess at the center configured to couple to a crossing rib support.

5. The particle shield of claim 1, wherein the height from the bottom surface of the annular ring to a top portion of the plurality of louver fins is about one inch or less.

6. The particle shield of claim 1, wherein each of the plurality of the rib supports is constructed from a single piece of aluminum bent to form recesses to house the bottom portion of each of the plurality of louver fins.

7. The particle shield of claim 1, wherein each plurality of cutaways of the annular ring is a bore hole through the annular ring.

8. The particle shield of claim 7, wherein each of the bore holes are further radially cut tangent to the bore hole toward the outer diameter of the annular ring.

9. A system for semiconductor processing comprising:
a chamber comprising one or more sidewalls, a bottom wall, and a lid enclosing a chamber interior volume;
a substrate support pedestal disposed within the chamber volume;
a vacuum pump coupled to the chamber and in fluid communication with the chamber interior volume;
a valve positioned between the chamber and the vacuum pump and configured to isolate the vacuum pump from the chamber interior volume;
a louver particle shield positioned between the vacuum pump and the chamber, the louver particle shield comprising:
an annular ring having a top surface and a bottom surface, the annular ring having a plurality of cutaways, the top surface of the annular ring having an upper outer portion and a lower inner portion;
a plurality of rib supports disposed on and supported by the lower inner portion of the annular ring; and
a plurality of louver fins having a truncated conical shape, a bottom surface of the louver fins supported in a recess formed in a top surface of the rib supports, each of the plurality of louver fins disposed between adjacent concentric louver fins has an outer diameter greater than an inner diameter of the outwardly adjacent louver fin.

10. The system of claim 9, wherein the plurality of louver fins are made from polished aluminum.

11. The system of claim 9, wherein the annular ring comprises a seal recess between the outer and inner diameter of the upper outer annular ring

12. The system of claim 9, wherein each of the plurality of louver fins is oriented at an angle of 10 to 45 degrees relative to the bottom surface of the annular ring.

13. The system of claim 10, wherein each of the plurality of the rib supports is constructed from machined aluminum.

14. The system of claim 10, wherein each of the plurality of the rib supports is constructed from a single piece of aluminum bent to form recesses to house the bottom portion of each of the plurality of louver fins.

15. The system of claim 9, wherein each plurality of cutaways of the annular ring is a bore hole through the annular ring.

16. The system of claim 15, wherein each of the bore holes are further radially cut tangent to the bore hole toward the outer diameter of the annular ring.

17. The system of claim 9, further comprising a screen disposed between the louver particle shield and the valve.

18. The system of claim 9, further comprising a screen disposed between the valve and the vacuum pump.

19. The system of claim 9, wherein louver particle shield is made from aluminum.

20. The system of claim 19, wherein the height from the bottom surface of the annular ring to a top portion of the plurality of louver fins is about one inch or less.
